(19) United States
(12) Patent Application Publication
(10) Pub. No.: US 2024/0310489 A1
(43) Pub. Date: Sep. 19, 2024

(54) ILLUMINATION DEVICE AND DISTANCE MEASURING DEVICE

(71) Applicant: SONY SEMICONDUCTOR SOLUTIONS CORPORATION, Kanagawa (JP)

(72) Inventors: Takashi KOBAYASHI, Kanagawa (JP); Tatsuya OIWA, Kanagawa (JP); Motoi KIMURA, Kanagawa (JP); Jialun XU, Kanagawa (JP)

(21) Appl. No.: 18/279,817

(22) PCT Filed: Feb. 15, 2022
(86) PCT No.: PCT/JP2022/005970

§ 371 Date: Aug. 31, 2023

(30) Foreign Application Priority Data
Mar. 31, 2021 (JP) 2021-062059

(51) Int. Cl. G01S 7/481; G01S 17/89

(52) U.S. Cl. CPC G01S 7/4815; G01S 17/89

(57) ABSTRACT

For example, an illumination device with improved uniform irradiation characteristics is provided.

The illumination device includes: a light emitting element including a plurality of first light emission units and a plurality of second light emission units; a first optical member that emits a plurality of first light emitted from the plurality of first light emission units and a plurality of second light emitted from the plurality of second light emission units in substantially parallel to each other; a second optical member that shapes a beam shape of at least one of the plurality of first light or the plurality of second light, and emits the plurality of first light and the plurality of second light as light having different beam shapes; and a third optical member, in which the third optical member is disposed on optical paths of the plurality of first light and the plurality of second light, and an action on the plurality of first light by the third optical member is different from an action on the plurality of second light by the third optical member.

### TECHNICAL FIELD

The present technology relates to an illumination device and a distance measuring device.

### BACKGROUND ART

An illumination device that irradiates a target object with a light beam is used for applications such as measurement of a spatial propagation time (TOF: Time of Flight) of light, measurement of a distance by structured light, and shape recognition of an object. Some distance measuring devices include an illumination device using, for example, a surface emitting semiconductor laser (VCSEL: Vertical Cavity Surface Emitting Laser) as a light emitting element and a distance measuring device including the illumination device. As a method for widely measuring a short distance using the ToF method, there is a method in which light emitted from a plurality of light emission units is diffused by a diffusion plate, the entire measurement target range is uniformly irradiated (hereinafter, also referred to as uniform irradiation as appropriate), and the entire measurement target range is detected by a photodetector having a light receiving unit divided two-dimensionally. As a method for extending the distance measurement distance, there is a method in which light emitted from a plurality of light emission units is made substantially parallel by a collimator lens, and a measuring target object is irradiated (hereinafter, also referred to as spot irradiation as appropriate) with a point-shaped light beam. In addition, a method of realizing spot irradiation and uniform irradiation by shifting the entire focal point of the spot light has also been proposed (see Patent Document 1).

### CITATION LIST

### Patent Document

Patent Document 1: US Patent Application Publication No. 2019/0018137 Specification

### SUMMARY OF THE INVENTION

### Problems to be Solved by the Invention

In this field, it is desired to improve uniformity of uniform irradiation without reducing the light intensity of spot irradiation.

An object of the present technology is to provide an illumination device in which uniformity of uniform irradiation is improved without reducing light intensity of spot irradiation, and a distance measuring device including the illumination device.

### Solutions to Problems

The present technology is an illumination device including:
a light emitting element including a plurality of first light emission units and a plurality of second light emission units;
a first optical member that emits a plurality of first light emitted from the plurality of first light emission units and a plurality of second light emitted from the plurality of second light emission units in substantially parallel to each other;
a second optical member that shapes a beam shape of at least one of the plurality of first light or the plurality of second light, and emits the plurality of first light and the plurality of second light as light having different beam shapes; and
a third optical member,
in which the third optical member is disposed on optical paths of the plurality of first light and the plurality of second light, and an action on the plurality of first light by the third optical member is different from an action on the plurality of second light by the third optical member.

The present technology is a distance measuring device including:
the illumination device described above;
a control unit that controls the illumination device;
a light receiving unit that receives reflected light reflected from an irradiation target object; and
a distance measuring unit that calculates a distance from image data obtained by the light receiving unit.

### BRIEF DESCRIPTION OF DRAWINGS

FIG. 1 is a schematic cross-sectional view of an illumination device according to an embodiment.

FIG. 2 is a block diagram illustrating an example of a schematic configuration of a distance measuring device including an illumination device.

FIG. 3 is a diagram illustrating an irradiation pattern at the time of spot irradiation of the illumination device.

FIG. 4 is a diagram illustrating an irradiation pattern at the time of uniform irradiation of the illumination device.

FIG. 5 is a diagram illustrating an irradiation pattern in a case where spot irradiation and uniform irradiation are simultaneously performed.

FIG. 6 is a schematic cross-sectional view illustrating an example of a light emitting element according to an embodiment.

FIG. 7 is a diagram illustrating an example of a configuration of a light emission unit according to an embodiment.

FIG. 8 is an enlarged view of a configuration of a light emission unit according to an embodiment.

FIG. 9A is a schematic plan view illustrating an example of a configuration of a microlens array in FIG. 1, and FIG. 9B is a schematic view illustrating an example of a cross-sectional configuration of the microlens array in FIG. 1.

FIG. 10A is a schematic view illustrating a position of a light emission unit for uniform irradiation with respect to the microlens array illustrated in FIG. 9A, and FIG. 10B is a schematic view illustrating a position of a light emission unit for spot irradiation with respect to the microlens array illustrated in FIG. 9A.

FIG. 11 is a diagram for explaining a beam forming function according to an embodiment.

FIG. 12 is a diagram illustrating an irradiation pattern for a target object according to an embodiment.

FIG. 13 is a schematic view illustrating an example of a diffraction element.

FIG. 14 is a schematic view illustrating a pattern of a light beam that has passed through a diffraction element.

FIGS. 15A and 15B are schematic cross-sectional views of a diffraction element according to an embodiment.

FIGS. 16A and 16B are schematic views illustrating a liquid crystal element applicable instead of the diffraction element.

FIGS. 17A and 17B are schematic views illustrating metamaterial applicable instead of the diffraction element.

FIG. 18 is a diagram illustrating an example of a configuration of a drive circuit of the illumination device.

FIG. 19 is a diagram illustrating another example of the configuration of the drive circuit of the illumination device.

FIG. 20 is a diagram for explaining a light emission sequence of the illumination device.

FIG. 21 is a diagram illustrating a first example of grouping of light emitting elements according to a modification.

FIG. 22 is a diagram illustrating a second example of grouping of light emitting elements according to a modification.

FIG. 23 is a diagram illustrating a third example of grouping of light emitting elements according to a modification.

FIG. 24 is a diagram illustrating a fourth example of grouping of light emitting elements according to a modification.

FIG. 25 is a diagram illustrating an example of a top view of a semiconductor laser driving apparatus in an application example.

FIG. 26 is a diagram illustrating an example of a cross-sectional view of a semiconductor laser driving apparatus in an application example.

FIG. 27 is a diagram illustrating another example of the cross-sectional view of the semiconductor laser driving apparatus in the application example.

### MODE FOR CARRYING OUT THE INVENTION

Hereinafter, embodiments and the like of the present technology will be described with reference to the drawings. Note that description will be given in the following order.
<1. Embodiment>
<2. Modification>
<3. Application Example>

### 1. Embodiment

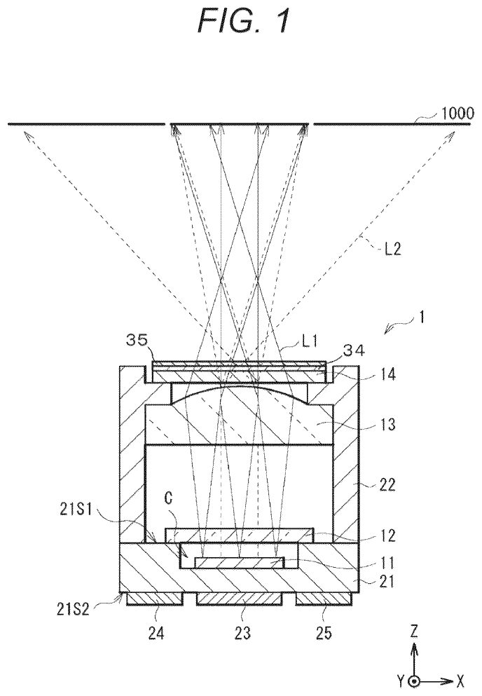

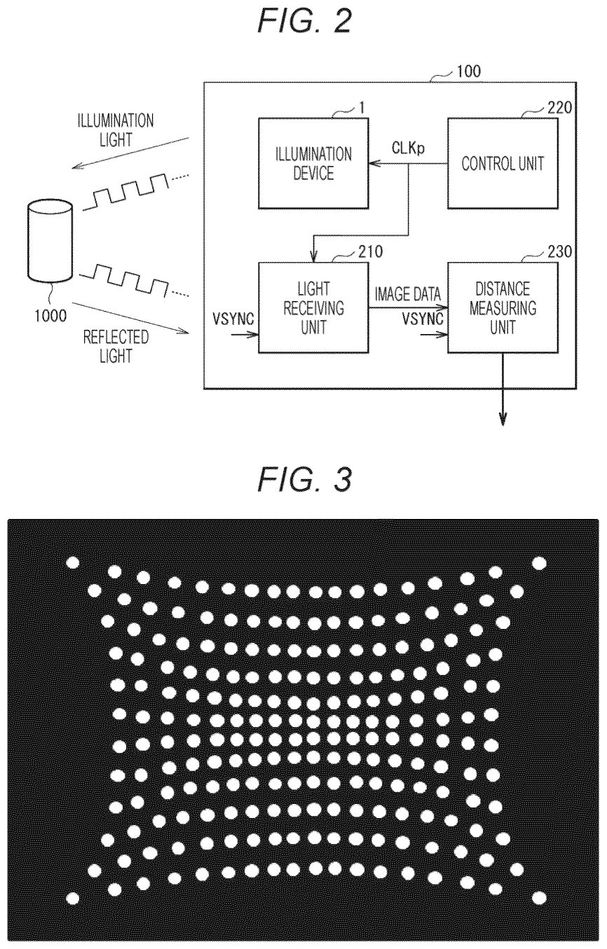

FIG. 1 is a cross-sectional view schematically illustrating an example of a schematic configuration of an illumination device (illumination device 1) according to an embodiment of the present technology. FIG. 2 is a block diagram illustrating a schematic configuration of a distance measuring device (distance measuring device 100) including the illumination device 1 illustrated in FIG. 1. The distance measuring device 100 includes the illumination device 1, a control unit 220 that controls the illumination device 1, a light receiving unit 210 that receives reflected light reflected from a distance measuring target object, and a distance measuring unit 230 that calculates a distance from image data obtained by the light receiving unit 210.

The distance measuring device 100 employs, for example, a time of flight (ToF) method or a structured light method. The ToF method is a method of calculating the distance from the time until the light beam emitted from the distance measuring device is reflected by the measuring target object and returns to the distance measuring device. The structured light method is a method of irradiating a measuring target object with a pattern of a light beam from a distance measuring device and calculating a distance from distortion of the pattern of the light beam reflected and returned to the distance measuring device.

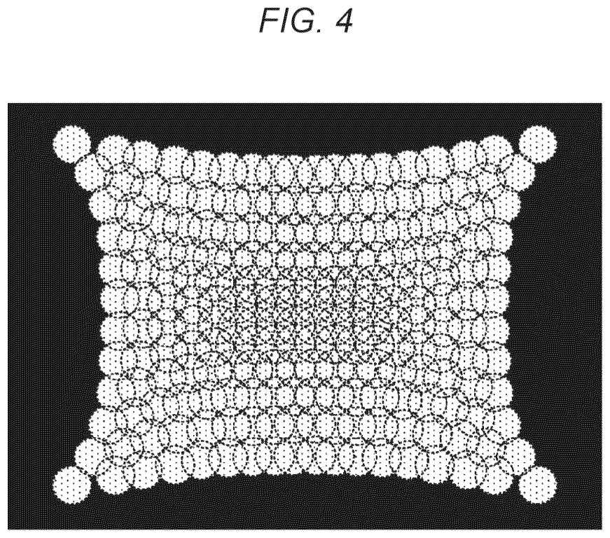

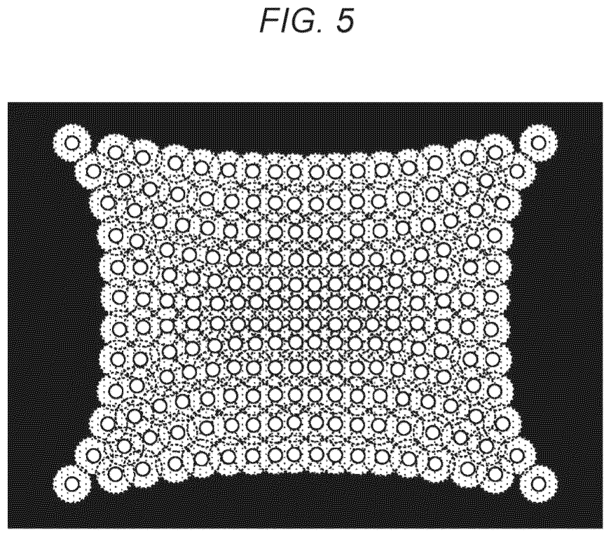

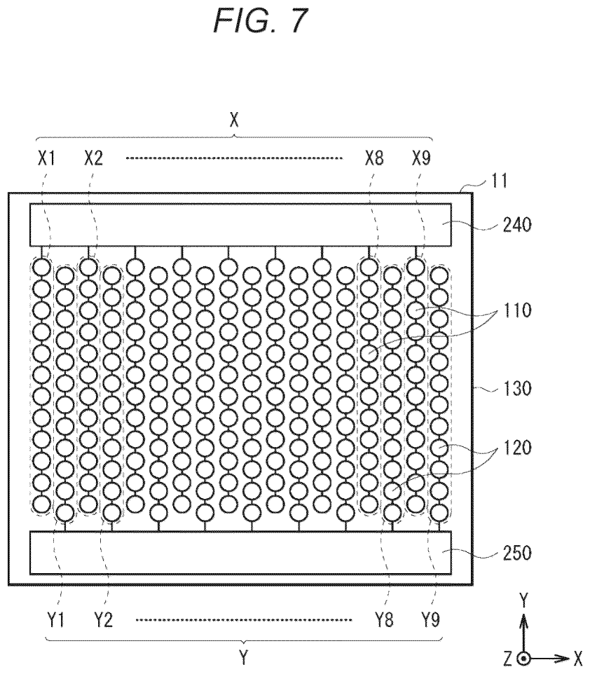

The illumination device 1 according to the embodiment emits light from a plurality of light emission units (light emission units 110 (first light emission unit) and 120 (second light emission unit), see FIG. 7). A diffraction element 14 to be described later is an optical element that tiles the light L1 and widens the irradiation range to the light L2, and it is possible to widen the irradiation range by tiling to 3×3. The light L110 and L120 perform, for example, spot irradiation as illustrated in FIG. 3, uniform irradiation as illustrated in FIG. 4, and simultaneous irradiation as illustrated in FIG. 5.

### [Configuration of Illumination Device]

The illumination device 1 includes, for example, a light emitting element 11, a microlens array 12 (an example of a second optical member), a collimator lens 13 (an example of a first optical member), the diffraction element 14, a diffraction element 34, and a ¼ wavelength plate 35.

The microlens array 12, the collimator lens 13, the diffraction element 14, the diffraction element 34, and the ¼ wavelength plate 35 are arranged, for example, in this order on an optical path of light (light L1 and L2) emitted from the light emitting element 11. The light emitting element 11 and the microlens array 12 are held by, for example, a holding unit 21, and the collimator lens 13 and the diffraction element 14 are held by, for example, a holding unit 22. The holding unit 21 includes, for example, one anode electrode unit 23 and two cathode electrode units 24 and 25 on a surface 21S2 opposite to a surface 21S1 holding the light emitting element 11 and the microlens array 12. Hereinafter, each member constituting the illumination device 1 will be described in detail.

### (Light Emitting Element)

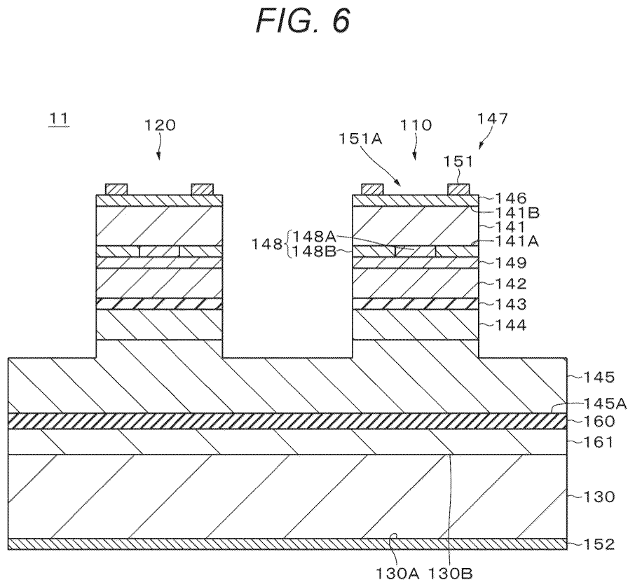

The light emitting element 11 is, for example, a surface emitting type surface emitting semiconductor laser. FIG. 6 schematically illustrates an example of a cross-sectional configuration of a light emission unit (light emission units 110 and 120) of the light emitting element 11. Note that, although two light emission units (light emission units 110 and 120) are illustrated in FIG. 6, the number of light emission units only needs to be at least two. Furthermore, the description of the light emission unit 110 can also be applied to the light emission unit 120 unless otherwise specified.

The light emitting element 11 schematically includes an n-type substrate 130 having a main surface 130A and a main surface 130B that is a main surface opposite to the main surface 130A, a lower electrode 152 provided on the main surface 130A of the n-type substrate 130, a p-type DBR layer 145 provided on the main surface 130B side of the n-type substrate 130 and having a main surface 145A, and at least two light emission units (for example, the light emission units 110 and 120) provided on the side opposite to the main surface 145A of the p-type DBR layer 145.

In addition, a tunnel junction layer 160 is provided between the main surface 130B of the n-type substrate and the main surface 145A of the p-type DBR layer 145. Note that the term “between” only needs to be provided therebetween, and does not necessarily need to be in contact. In addition, the term “side” only needs to exist in the direction, and does not necessarily need to be in contact. The light emission unit 110 is laminated on the p-type DBR layer 145 and includes an n-type DBR layer 141 having a main surface 141A and a main surface 141B opposite to the main surface 141A, and an upper electrode 151 (an example of a second electrode) provided on the main surface 141B side of the n-type DBR layer 141. In addition, the light emitting element 11 has a cathode electrode extraction unit divided into at least two regions. For example, the upper electrode 151 of the light emission unit 110 is connected to an electrode pad 240, and the upper electrode 151 of the light emission unit 120 is connected to an electrode pad 250.

More specifically, an n-type buffer layer 161 is provided between the main surface 130A of the n-type substrate 130 and the tunnel junction layer 160. In addition, the light emission unit 110 has a configuration in which a p-type spacer layer 144, an active layer 143, an n-type spacer layer 142, an n-type buffer layer 149, a current confinement layer 148, an n-type DBR layer 141, and an n-type contact layer 146 are sequentially laminated from the side opposite to the main surface 145A of the p-type DBR layer 145, and this configuration (hereinafter, also referred to as a semiconductor layer as appropriate) is a columnar mesa portion 147. The upper electrode 151 is attached to the n-type contact layer 146. Hereinafter, details of each configuration of the light emitting element 11 will be described.

The n-type substrate 130 is, for example, an n-type GaAs substrate. Examples of an n-type impurity include, for example, silicon (Si), selenium (Se) or the like. The semiconductor layers are each constituted by, for example, an AlGaAs-based compound semiconductor. The AlGaAs-based compound semiconductor refers to a compound semiconductor containing at least aluminum (Al) and gallium (Ga) among Group 13 elements in the periodic table of elements and at least arsenic (As) among Group 15 elements in the periodic table of elements.

The n-type DBR layer 141 is formed by alternately laminating a low refractive index layer and a high refractive index layer (both not illustrated). The low refractive index layer is constituted by, for example, n-type Alₓ₁Ga₁₋ₓ₁As (0<x1<1) having a thickness of λ₀/4n₁ (λ₀ represents an emission wavelength, and n₁ represents a refractive index). The high refractive index layer is constituted by, for example, n-type Alₓ₂Ga₁₋ₓ₂As (0<x2<x1) having a thickness of λ₀/4n₂ (n2 is a refractive index).

The n-type spacer layer 142 is constituted by, for example, n-type Alₓ₃Ga₁₋ₓ₃As (0<x3<1). The p-type spacer layer 144 is constituted by, for example, p-type Alₓ₅Ga₁₋ₓ₅As (0<x5<1). Examples of the p-type impurity include zinc (Zn), magnesium (Mg), and beryllium (Be).

The active layer 143 has a multi quantum well structure (MQW). The active layer 143 has, for example, a structure in which a thin film of n-type Alₓ₆Ga₁₋ₓ₆As (0<x6<1) and a tunnel junction layer are alternately laminated.

The p-type DBR layer 145 is formed by alternately laminating a low refractive index layer and a high refractive index layer (both not illustrated). The low refractive index layer is constituted by, for example, p-type Alₓ₈Ga₁₋ₓ₈As (0<x8<1) having a thickness of λ₀/4n₃ (n₃ is a refractive index). The high refractive index layer is constituted by, for example, p-type Alₓ₉Ga₁₋ₓ₉As (0<x9<x8) having a thickness of λ₀/4n₄ (n₄ is a refractive index). The contact layer 16 is constituted by, for example, p-type Alx₁₀Ga₁₋ₓ₁₀As (0<x10<1).

The current confinement layer 148 and the n-type buffer layer 149 are provided in the n-type DBR layer 141, for example. The current confinement layer 148 is formed at a position away from the active layer 143 in relation to the n-type buffer layer 149. The current confinement layer 148 is provided, for example, in place of the low refractive index layer in a portion of the low refractive index layer that is, for example, several layers away from the active layer 143 side in the n-type DBR layer 141. The current confinement layer 148 has a current injection region 148A and a current confinement region 148B. The current injection region 148A is formed in a central region in the plane. The current confinement region 148B is formed in a peripheral edge of the current injection region 148A, that is, an outer edge region of the current confinement layer 148, and has an annular shape.

The current injection region 148A is constituted by, for example, n-type Alₓ₁₁Ga₁₋ₓ₁₁As (0.98≤x11≤1). The current confinement region 148B is constituted by, for example, aluminum oxide (Al₂O₃), and is obtained by oxidizing an oxidized layer (not illustrated) constituted by, for example, n-type Alₓ₁₁Ga₁₋ₓ₁₁As from the side surface of the mesa portion 147. As a result, the current confinement layer 148 has a function of constricting the current.

The n-type buffer layer 149 is formed closer to the active layer 143 in relation to the current confinement layer 148. The n-type buffer layer 149 is formed adjacent to the current confinement layer 148. For example, as illustrated in FIG. 6, the n-type buffer layer 149 is formed in contact with a surface (lower surface) of the current confinement layer 148 on the active layer 143 side. Note that a thin layer having a thickness of, for example, about several nm may be provided between the current confinement layer 148 and the n-type buffer layer 149. The n-type buffer layer 149 is provided, for example, in place of the high refractive index layer in a portion of the high refractive index layer that is, for example, several layers away from the current confinement layer 148 in the n-type DBR layer 141.

The n-type buffer layer 149 has an unoxidized region and an oxidized region (both not illustrated). The unoxidized region is mainly formed in a central region in the plane, and is formed, for example, at a portion in contact with the current injection region 148A. The oxidized region is formed on a peripheral edge of the unoxidized region and has an annular shape. The oxidized region is mainly formed in the outer edge region in the plane, and is formed, for example, in a portion in contact with the current confinement region 148B. The oxidized region is formed to be biased toward the current confinement layer 148 side in a portion other than the portion corresponding to the outer edge of the n-type buffer layer 149.

The unoxidized region is constituted by a semiconductor material containing Al, and is constituted by, for example, n-type Alₓ₁₂Ga₁₋ₓ₁₂As (0.85<x12≤0.98) or n-type InaAlₓ₁₃Ga₁₋ₓ₁₃₋ₐAs (0.85<x13<0.98). The oxidized region includes, for example, aluminum oxide (Al₂O₃), and is obtained by oxidizing a layer to be oxidized (not illustrated) including, for example, n-type Alₓ₁₂Ga₁₋ₓ₁₂As or n-type In Alₓ₁₃Ga_{1-x13-b}As from the side surface side and the layer to be oxidized side of the mesa portion 147. The layer to be oxidized of the n-type buffer layer 149 is constituted by a material and a thickness that have a higher oxidation rate than the p-type DBR layer 145 and the n-type DBR layer 141 and a lower oxidation rate than the layer to be oxidized of the current confinement layer 148.

The tunnel junction layer 160 is a substance through which a tunnel current flows during energization in this section, and is constituted by, for example, a highly doped n-type and p-type Alₓ₁₄Ga₁₋ₓ₁₄As (0<x14<1) thin film. The tunnel junction layer 160 may be any substance as long as a tunnel current flows therethrough as exemplified. The n-type buffer layer 161 is provided between the tunnel junction layer 160 and the n-type substrate 130. As the n-type buffer layer, a similar one to the n-type buffer layer 149 can be applied.

On the upper surface of the mesa portion 147 (the upper surface of the n-type contact layer 146), the annular upper electrode 151 having an opening (light emission port 151A) in a region facing at least the current injection region 148A is formed. In addition, an insulating layer (not illustrated) is formed on a side surface and a peripheral surface of the mesa portion 147. The upper electrode 151 is connected to the electrode pad 240 or the electrode pad 250 by wiring (not illustrated) for each of light emission unit groups X1 to X9 and light emission unit groups Y1 to Y9 (see FIG. 7). For example, the electrode pad 240 or the electrode pad 250 is electrically connected by wire bonding. In addition, the lower electrode 152 is provided on the other surface of the n-type substrate 130. The lower electrode 152 is electrically connected to, for example, the anode electrode unit 23. As described above, the embodiment is an embodiment in which the anode electrode unit is a common electrode, and the cathode electrode unit is separately provided.

Here, the upper electrode 151 is formed by, for example, laminating titanium (Ti), platinum (Pt), and gold (Au) in this order, and is electrically connected to the n-type contact layer 146 above the mesa portion 147. The lower electrode 152 has a structure in which, for example, an alloy of gold (Au) and germanium (Ge), nickel (Ni), and gold (Au) are laminated in order from the n-type substrate 130 side, and is electrically connected to the n-type substrate 130.

### (Light Emission Unit)

The plurality of light emission units has a configuration in which, for example, a plurality of light emission units (a plurality of light emission units 110 for spot irradiation) used for spot irradiation and a plurality of light emission units (a plurality of light emission units 120 for uniform irradiation) used for uniform irradiation are arranged in an array on the n-type substrate 130. The plurality of light emission units 110 and the plurality of light emission units 120 are electrically separated from each other. In the present embodiment, the polarization directions of the laser beams L110 emitted from the plurality of light emission units 110 are different from the polarization directions of the laser beams L120 emitted from the plurality of light emission units 120.

The above-described light emitting element 11 has two mesa portions 147, but the distance measuring device 100 has a plurality of light emission units, for example, a plurality of light emission units 110 and a plurality of light emission units 120. The plurality of light emission units 110 and the plurality of light emission units 120 are electrically connected to each other. Specifically, for example, as illustrated in FIG. 7, the plurality of light emission units 110 constitutes a plurality of (for example, nine in FIG. 7) light emission unit groups X (light emission unit groups X1 to X9) including n (for example, 12 in FIG. 7) light emission units 110 extending in one direction (for example, in the Y-axis direction). Similarly, the plurality of light emission units 120 constitutes a plurality of (for example, nine in FIG. 7) light emission unit groups Y (light emission unit groups Y1 to Y9) including m (for example, 12 in FIG. 7) light emission units 120 extending in one direction (for example, in the Y-axis direction). As illustrated in FIG. 7, the light emission unit groups X1 to X9 and the light emission unit groups Y1 to Y9 are alternately arranged on the n-type substrate 130 having a rectangular shape, for example. The light emission unit groups X1 to X9 are electrically connected to, for example, the electrode pad 240 provided along one side of the n-type substrate 130, and the light emission unit groups Y1 to Y9 are electrically connected to, for example, the electrode pad 250 provided along another side facing the one side of the n-type substrate 130. Note that, although FIG. 7 illustrates an example in which the light emission unit groups X1 to X9 and Y1 to Y9 are alternately arranged, the present invention is not limited thereto. For example, the number of the plurality of light emission units 110 and the number of the plurality of light emission units 120 can be arbitrarily arranged depending on the number and position of desired light emission points and the amount of light output. As an example, the plurality of light emission units 120 may be arranged in every two rows of the plurality of light emission units 110.

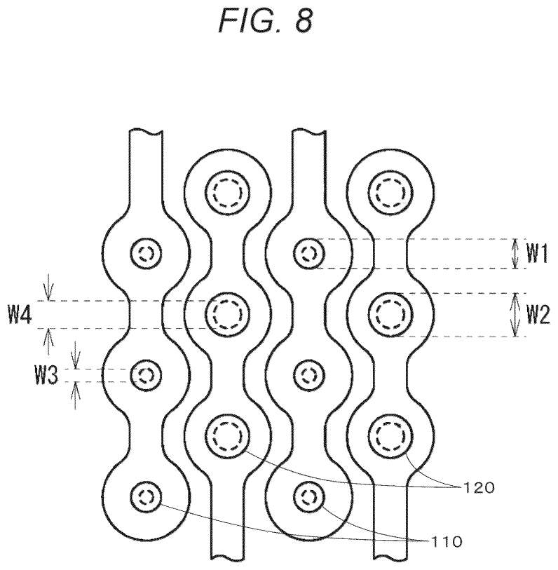

FIG. 8 is an enlarged view of a part of the arrangement of the plurality of light emission units 110 and the plurality of light emission units 120 illustrated in FIG. 7. The plurality of light emission units 110 and the plurality of light emission units 120 preferably have different light emission areas (OA diameters W3 and W4). Specifically, the light emission area (OA diameter W3) of the plurality of light emission units 110 for spot irradiation is preferably smaller than the light emission area (OA diameter W4) of the plurality of light emission units 120 for uniform irradiation. As a result, the light beams for spot irradiation (the laser beam L110 (first light) emitted to the irradiation target object 1000 in a spot shape independent from each other, see FIG. 12) emitted from the plurality of light emission units 110 are condensed smaller, and the target object can be irradiated with a smaller spot. In addition, a wider range can be irradiated with the light beams for uniform irradiation (the laser beam L120 (second light) is overlapped on the light emitted from the adjacent light emission units 120, so that the predetermined range is irradiated with the laser beam L120 in a substantially uniform manner with respect to the irradiation target object 1000, see FIG. 12) emitted from the plurality of light emission units 120, and the irradiation target object 1000 can be uniformly irradiated with light beams with higher output and more uniform. In addition, accordingly, opening width W1 of the wiring connecting each of the plurality of light emission units 110 becomes smaller than opening width W2 of the wiring connecting each of the plurality of light emission units 120. Although the number of light emission units for spot irradiation and the number of light emission units for uniform irradiation are the same, they may be different. Further, the light emission unit for spot irradiation and the light emission unit for uniform irradiation may have different far field patterns (FFPs).

### (Microlens Array, Collimator Lens, and Diffraction Element)

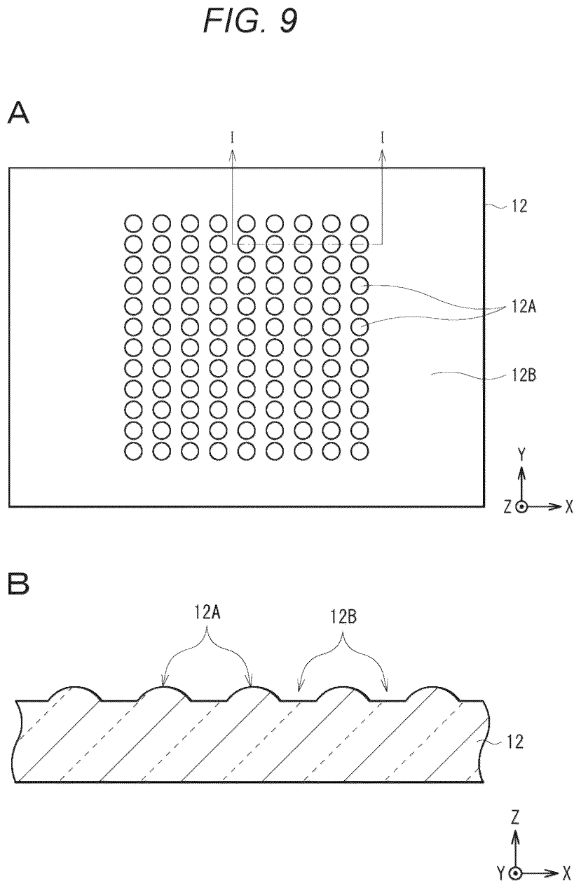

For example, the microlens array 12 forms a shape of at least one beam of light (laser beam L110 or laser beam L120) emitted from the plurality of the light emission units 110 for spot irradiation and the plurality of the light emission units 120 for uniform irradiation and emits the beam. FIG. 9A schematically illustrates an example of a planar configuration of the microlens array 12, and FIG. 9B schematically illustrates a cross-sectional configuration of the microlens array 12 taken along line I-I illustrated in FIG. 9A. In the microlens array 12, a plurality of microlenses is disposed in an array, and the microlens array 12 includes a plurality of lens portions 12A and a parallel plate portion 12B.

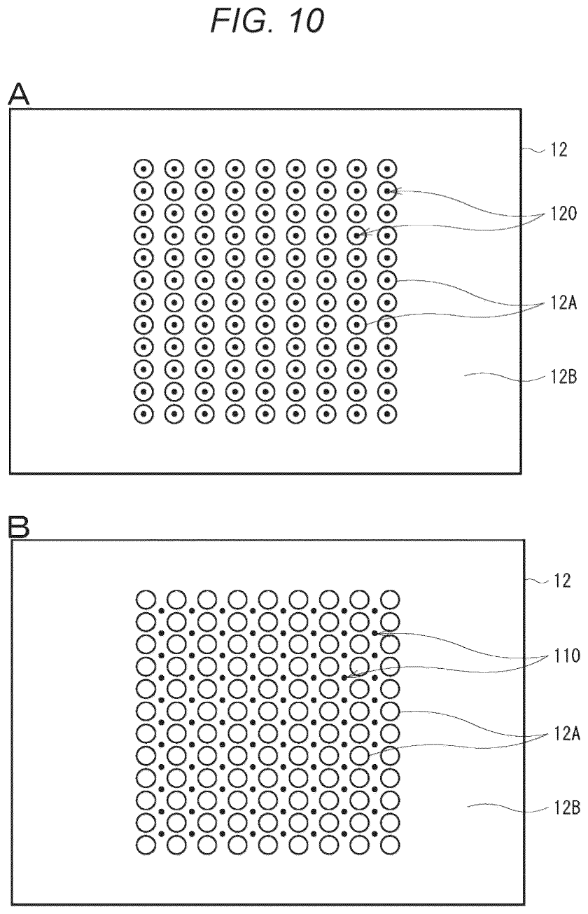

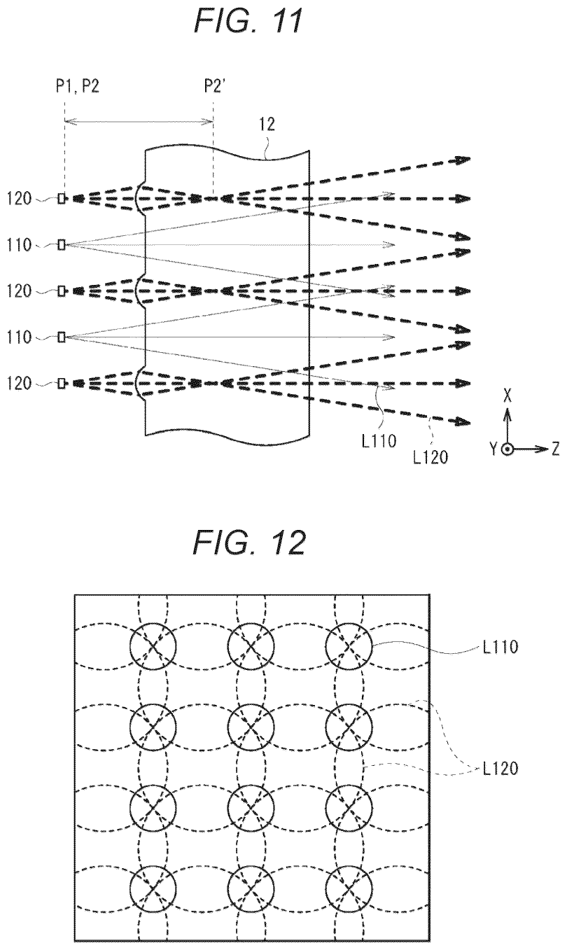

In the embodiment, as illustrated in FIG. 10A, the microlens array 12 is disposed such that the lens portions 12A respectively face the plurality of light emission units 120 for uniform irradiation, and as illustrated in FIG. 10B, the parallel plate portion 12B faces the plurality of light emission units 110 for spot irradiation. Therefore, as illustrated in FIG. 11, each of the laser beams L120 emitted from the plurality of the light emission units 120 is refracted by a lens surface of each of the lens portions 12A, and for example, forms a virtual light emission point P2′ in the microlens array 12. That is, a light emission point P2 of each of the plurality of light emission units 120 at the same height as a light emission point P1 of each of the plurality of light emission units 110 is shifted in an optical axis direction (for example, in the Z-axis direction) of the light beams (the laser beams L110 and the laser beams L120) emitted from the plurality of light emission units 110 and the plurality of light emission units 120.

Therefore, by switching the light emission of the plurality of light emission units 110 and the plurality of light emission units 120, the laser beams L110 emitted from the plurality of light emission units 110 pass through the microlens array 12 as they are, and form a spot-shaped irradiation pattern as illustrated in FIGS. 3 and 12, for example. Further, the laser beams L120 emitted from the plurality of light emission units 120 are refracted by the microlens array 12, and for example, as illustrated in FIGS. 4 and 12, partially overlap the laser beams L120 emitted from the adjacent light emission units 120, thereby forming an irradiation pattern for irradiating a predetermined range with substantially uniform light intensity. In the illumination device 1, by switching between the light emission of the plurality of light emission units 110 and the light emission of the plurality of light emission units 120, it is possible to switch between spot irradiation and uniform irradiation.

Note that FIG. 11 illustrates an example in which the microlens array 12 functions as a relay lens, but the present technology is not limited thereto. For example, the virtual light emission point P2′ of the plurality of light emission units 120 may be formed between the light emission unit 120 and the microlens array 12.

The collimator lens 13 emits the laser beams L110 emitted from the plurality of light emission units 110 and the laser beams L120 emitted from the plurality of light emission units 120 as substantially parallel light. The collimator lens 13 is, for example, a lens for collimating each of the laser beam L110 and the laser beam L120 emitted from the microlens array 12 to couple with the diffraction element 14.

The diffraction element 14 divides and emits each of the laser beams L110 emitted from the plurality of light emission units 110 and the laser beams L120 emitted from the plurality of light emission units 120. As the diffraction element 14, for example, a diffractive optical element (DOE) that divides the laser beams L110 emitted from the plurality of light emission units 110 and the laser beams L120 emitted from the plurality of light emission units 120 into 3×3 can be used. By disposing the diffraction element 14, it is possible to tile the light fluxes of the laser beam L110 and the laser beam L120, for example, to increase the number of spots at the time of spot irradiation or to expand the irradiation range at the time of uniform irradiation.

### (Holding Unit)

The holding unit 21 and the holding unit 22 are for holding the light emitting element 11, the microlens array 12, the collimator lens 13, and the diffraction element 14. Specifically, the holding unit 21 holds the light emitting element 11 in a recess C provided on the upper surface (surface 211), and holds the microlens array 12 along the surface 21S1. The holding unit 22 holds the collimator lens 13 and the diffraction element 14. The microlens array 12, the collimator lens 13, and the diffraction element 14 are respectively held by the holding unit 21 and the holding unit 22 by, for example, an adhesive. The holding unit 21 and the holding unit 22 are connected to each other such that the light L1 (specifically, the laser beam L110) and the light L2 (specifically, the laser beam L120) emitted from the light emitting element 11 are incident on a predetermined position of the microlens array 12, and the light L1 and the light L2 transmitted through the collimator lens 13 become substantially parallel light.

A plurality of electrode units is provided on the back surface (surface 21S2) of the holding unit 21. Specifically, the anode electrode unit 23 common to the plurality of light emission units 110 for spot irradiation and the plurality of light emission units 120 for uniform irradiation, the cathode electrode unit 24 of the plurality of light emission units 110 for spot irradiation, and the cathode electrode unit 25 of the plurality of light emission units 120 for uniform irradiation are provided on the surface 212 of the holding unit 21.

Note that the configuration of the plurality of electrode units provided on the surface 21S2 of the holding unit 21 is not limited to the above, and for example, the anode electrode units of the plurality of light emission units 110 for spot irradiation and the plurality of light emission units 120 for uniform irradiation may be separately formed, or the anode electrode units of the plurality of light emission units 110 for spot irradiation and the plurality of light emission units 120 for uniform irradiation may be formed as the common electrode unit. In addition, FIG. 1 illustrates an example in which the microlens array 12 is held by the holding unit 21, but the present invention is not limited thereto, and for example, the microlens array may be held by the holding unit 22. The collimator lens 13 and the diffraction element 14 may be held by the holding unit 21.

### (Third Optical Member)

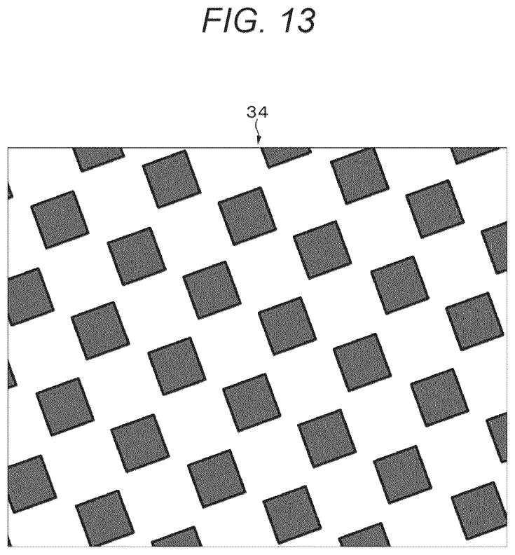

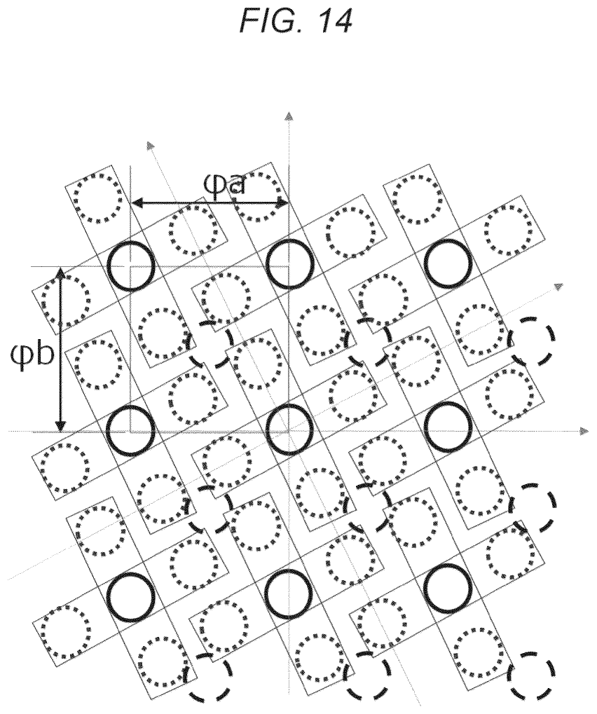

FIG. 13 illustrates a shape of the diffraction element 34 according to the embodiment. In the embodiment, the diffraction element 34 diffracts (or refracts) the light beam emitted from the light emission unit for uniform irradiation to increase the number of light beams. For example, one light beam can be divided into five as indicated by thin dotted circles and solid circles in FIG. 14. On the other hand, the light beam emitted from the light emission unit for spot irradiation is not diffracted by the diffraction element 34, the light beam is not divided, and the light beam is emitted as it is as indicated by thick dotted circles in FIG. 14. By the action of the diffraction element 34, the light beam for uniform irradiation is overlapped on the adjacent light beams, a range (overlapping range) in which the adjacent light beams are overlapped on each other is increased, and the light beams are emitted as more uniform light. Each light beam for spot irradiation is emitted with high light intensity without decreasing the light intensity.

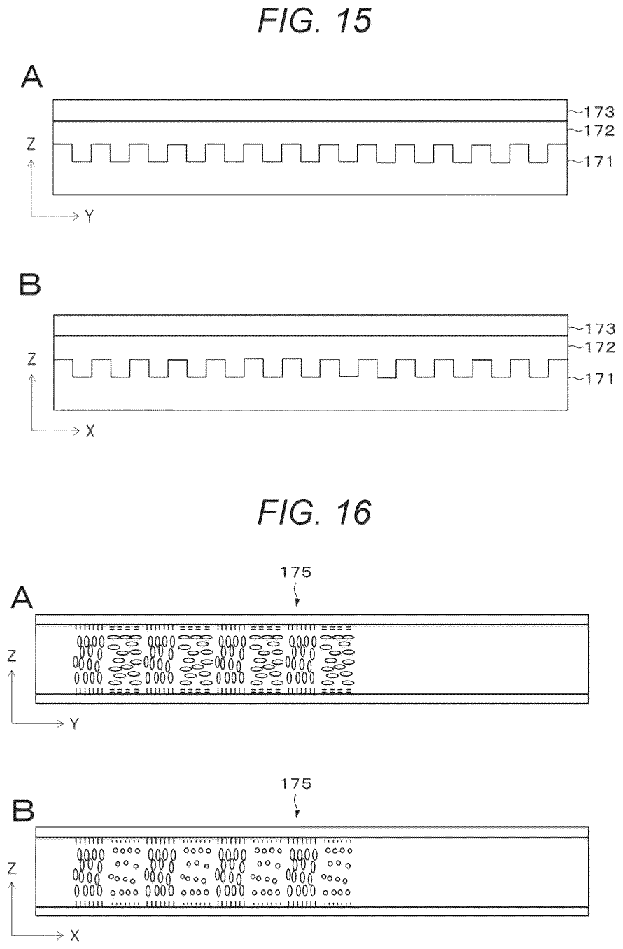

FIGS. 15A and 15B illustrate cross-sectional views of the diffraction element 34 in the embodiment. The diffraction element 34 in FIGS. 15A and 15B has, for example, a three-layer structure in which a first layer 171, a second layer 172, and a third layer 173 are bonded in this order, and the refractive index of the first layer 171 is n1 and the refractive index of the third layer 173 is n3. The refractive index of the second layer 172 varies depending on the direction, the refractive index in the Y direction illustrated in FIG. 15A is n2y, and the refractive index in the X direction illustrated in FIG. 8B is n2x. The diffraction element 34 having the three-layer structure is configured by overlapping anisotropic materials, and n1 and n2x are the same (n1=n2x), and n1 and n2y are different (n1≠n2y). Each layer can be constituted by any material as long as these refractive index relationships are satisfied.

As described above, the diffraction element 34 has different refractive indexes in the X direction and the Y direction, and thus acts as a parallel plate for polarized light in a certain direction (X direction) and acts as a diffraction element that diffracts (refracts) a light beam for polarized light in a direction (Y direction) orthogonal to the certain direction. As described above, the diffraction element 34 is a polarization diffraction element, and can refract or diffract the light beam traveling in a predetermined direction (specific direction) to change the polarization characteristic of the light beam emitted from the uniformly emitted light emission unit. Note that a volume hologram may be used instead of the diffraction element 34. Further, the diffraction element 34 may provide an action of refraction of light, and may be, for example, a Fresnel lens.

The diffraction element 34 diffracts or refracts the laser beam L120 emitted from the light emission unit for uniform irradiation, but does not act on the laser beam L110 emitted from the light emission unit for spot irradiation and transmits the laser beam as it is. That is, the diffraction element 34 acts differently on the laser beam L110 and the laser beam L120. As a result, it is possible to perform distance measurement without reducing the intensity of the light beam emitted from the light emission unit for spot irradiation. Note that the positions of the diffraction element 14 and the diffraction element 34 described above may be opposite to each other, and the optical diffraction surface may be disposed to overlap both surfaces of one optical element or one surface of one optical surface. In the case of overlapping, the function of the diffraction grating 14 exhibits a similar function regardless of the polarization direction of light.

Furthermore, the ¼ wavelength plate 35 is disposed on the diffraction element 34. With the ¼ wavelength plate 35, the light beam with which the distance measuring target object is irradiated becomes circularly polarized light, and it is possible to suppress a change in reflection characteristics due to the material and direction of the distance measuring target object. Note that both the diffraction element 34 and the ¼ wavelength plate 35 may be formed in one optical element.

### (Another Example of Third Optical Member)

Another example of the third optical member will be described. Instead of the diffraction element 34 described above, an organic liquid crystal element 175 schematically illustrated in FIGS. 16A and 16B and having different alignments in the X direction and the Y direction can be used. At this time, since the polarization direction of the beam light can be changed by switching the light emission of the VCSEL, it is not necessary to switch the alignment of the organic liquid crystal element 175 in order to change the polarization direction of the beam light. Therefore, a circuit configuration for switching the alignment of the organic liquid crystal element 175, a flexible cable, and the like are unnecessary, and the problem of the switching time of the alignment of the organic liquid crystal element 175 does not occur. An inorganic liquid crystal element may be used instead of the organic liquid crystal element 175. The inorganic liquid crystal element has better temperature characteristics and heat resistance than the organic liquid crystal element, and can also be used for applications requiring high reliability such as in-vehicle applications.

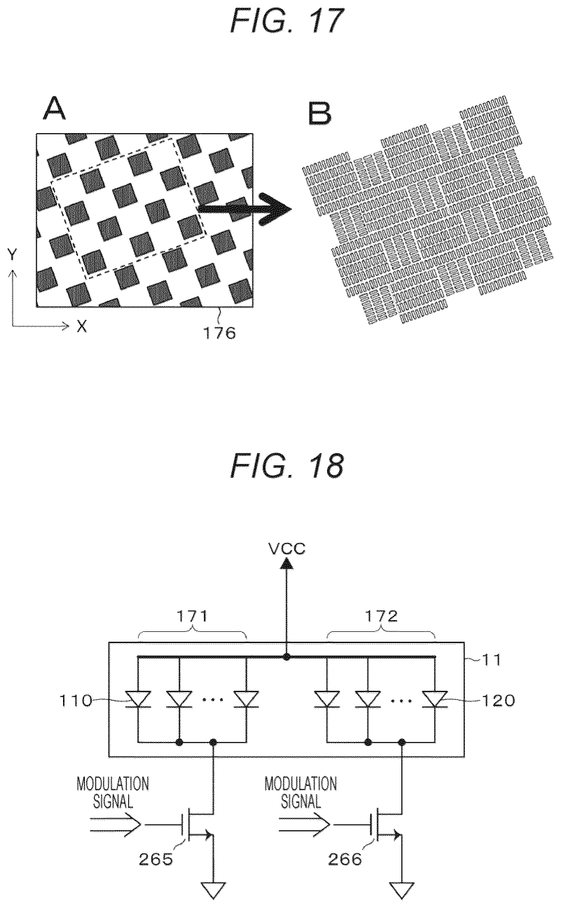

Instead of the diffraction element 34, a so-called metamaterial 176 having a microstructure on a scale equal to or less than the wavelength of the light beam, schematically illustrated in FIGS. 17A and 17B, can be used. FIG. 17B is an enlarged view of a portion of metamaterial 176 illustrated in FIG. 17A. The metamaterial 176 enables different diffraction characteristics to be generated depending on the polarization direction. By using the metamaterial 176, the polarized light can be changed together with the diffraction direction, and the metamaterial 176 can have the function (for example, a function of converting circularly polarized light into linearly polarized light) of the ¼ wavelength plate 35. That is, the configuration related to the ¼ wavelength plate 35 can be made unnecessary, and downsizing and cost reduction of the device can be achieved. Furthermore, the function of the collimator lens 13 may also be constituted by metamaterial, and the collimator lens 13, the diffraction element 34, and the ¼ wavelength plate 35 may be formed together in one optical element.

### [Method for Driving Illumination Device]

FIG. 18 illustrates an example of a configuration of a drive circuit of the illumination device 1. As illustrated in the drawing, anodes of a first light emission unit group 181 and a second light emission unit group 182 are connected to a power supply (VCC). In addition, a cathode of the first light emission unit group 181 is connected to a drive unit 265, and a cathode of the second light emission unit group 182 is connected to a drive unit 266. The first light emission unit group 181 is, for example, a set of light emission units 110 connected to the electrode pad 240. In addition, the second light emission unit group 182 is, for example, a set of light emission units 120 connected to the electrode pad 250. For example, the light emission unit group can be switched by outputting modulation signals from two driving units and an external changeover switch.

As the drive unit 265 and the drive unit 266, an n-type metal oxide semiconductor field effect transistor (MOSFET) can be applied. When a modulation signal that defines the timing of ON/OFF modulation is supplied, each of the drive unit 265 and the drive unit 266 connects the ground and the first light emission unit group 181 or the second light emission unit group 182 at the ON timing. As a result, a current flows through the first light emission unit group 181 and the second light emission unit group 182 at the ON timing, and light emission occurs. Since the cathodes of the first light emission unit group 181 and the second light emission unit group 182 are completely separated, and the drive unit 265 and the drive unit 266 are provided, respectively, it is possible to drive the first light emission unit group 181 and the second light emission unit group 182 with different waveforms (timing and current).

Note that each of the drive unit 265 and the drive unit 266 may be a P-type MOSFET or a bipolar transistor.

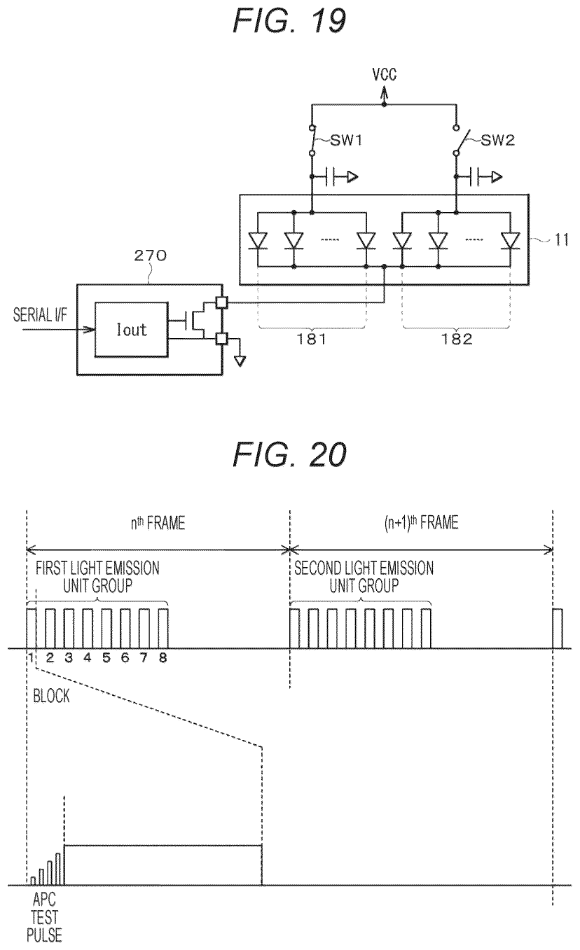

Note that the drive unit 265 and the drive unit 266 may be provided outside the illumination device 1, for example, or may be incorporated in the holding unit 21, for example. In addition, the light emitting element 11 and each drive unit may be directly connected. In the example illustrated in FIG. 18, the anode electrode is commonly used, but as illustrated in FIG. 19, a circuit configuration in which the cathode electrode is commonly used may be employed. In the circuit configuration illustrated in FIG. 19, switching between the first light emission unit group 181 and the second light emission unit group 182 is performed by complementarily turning on/off external switches SW1 and SW2 using one drive unit 270, for example.

FIG. 20 illustrates an example of a light emission sequence of the illumination device 1. A section in which one distance measurement image is generated is referred to as a “frame”, and one frame is set to, for example, a time of 33.3 msec (frequency of 30 Hz). As a distance measurement pulse, for example, a rectangular continuous wave of 100 MHz/Duty=50% is used, and this causes continuous light emission between accumulation sections. A plurality of the accumulation sections with different conditions can be provided in the frame. Although eight accumulation sections are illustrated in FIG. 20, the number of accumulation sections is not limited to this number.

As illustrated in the drawing, in the illumination device 1, the first light emission unit group 181 is caused to emit light in one frame, and the light receiving unit 210 (see FIG. 2) receives the reflected light and generates a distance measurement image. In the next frame, the second light emission unit group 182 is caused to emit light, and the light receiving unit 210 receives reflected light to generate a distance measurement image. Note that, in FIG. 20, the first light emission unit group 181 and the second light emission unit group 182 are switched in each frame, but may be switched in each plurality of frames. Note that light emission of the first light emission unit group 181 and the second light emission unit group 182 may be switched, for example, in units of one frame, in units of blocks, or in units of a plurality of blocks. Therefore, for example, it is possible to switch between spot irradiation and uniform irradiation at a faster speed as compared with a method of mechanically switching focal positions of laser beams emitted from a plurality of the light emission units.

According to the present embodiment, it is possible to increase the overlapping range of the uniform irradiation pattern by diffracting or refracting the light beam emitted from the light emission unit for uniform irradiation by the third optical member. As a result, the accuracy of distance measurement can be improved. Further, by preventing the third optical member from having any effect on the light beam emitted from the light emission unit for spot irradiation, distance measurement can be performed without reducing the intensity of the light beam emitted from the light emission unit for spot irradiation.

### 2. Modification

Although the embodiment of the present disclosure has been specifically described above, the contents of the present disclosure are not limited to the embodiment described above, and various modifications based on the technical idea of the present disclosure are possible. Hereinafter, each of a plurality of modifications will be described. Note that configurations identical or similar to those of the embodiment are denoted by the same reference numerals, and redundant description will be omitted as appropriate.

The microlens array 12 described in the embodiment may not be provided. In this case, for example, the laser beam L110 emitted from the light emission unit 110 is light for spot irradiation that passes through the diffraction element 14 and the like as it is, the laser beam L120 emitted from the light emission unit 120 is light for spot irradiation diffracted by the diffraction element 14 and the like, and the number of spots of the laser beam L120 is increased. Since the laser beam L110 has high light intensity, it is possible to perform distance measurement over a long distance, and since the laser beam L120 has a large number of spots, there is an advantage that the resolution is relatively high in distance measurement.

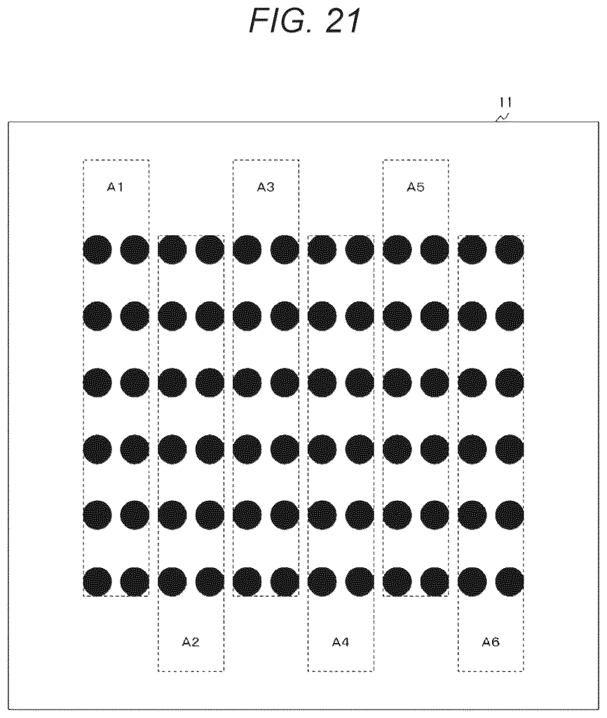

The light emitting elements 11 in the embodiment may be grouped. FIG. 21 to FIG. 23 are diagrams illustrating an example of grouping of the light emitting elements 11 according to an application example of the present technology.

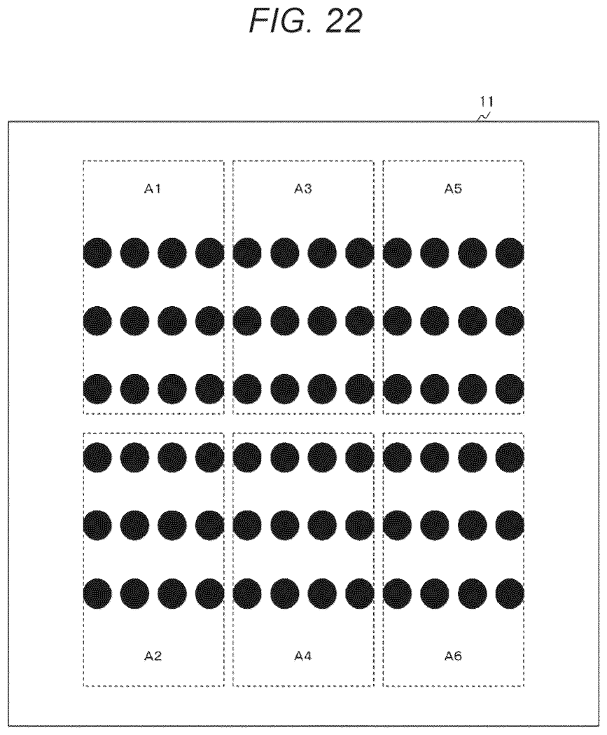

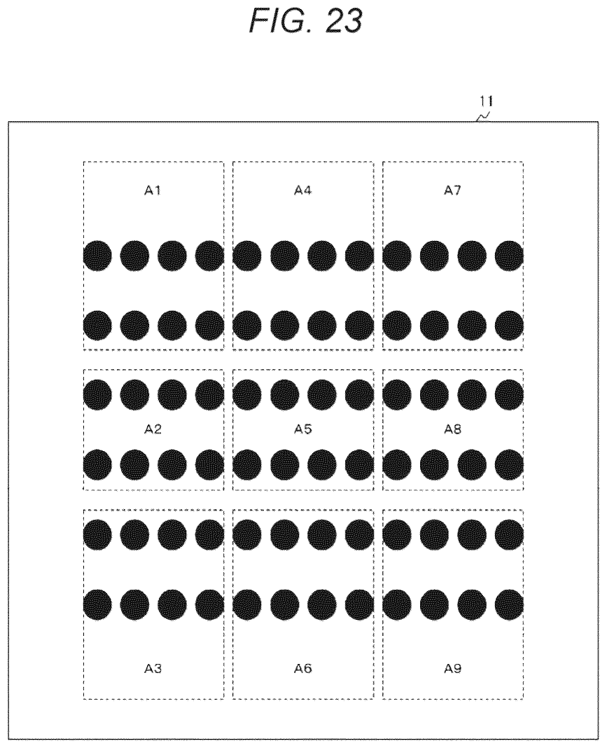

In the example illustrated in FIG. 21, a case is assumed where one region is formed for every plurality of columns (two columns in this example) and switching is performed for each region. In the example illustrated in FIG. 22, a case is assumed where one frame is further vertically divided into two to form quadrangle regions and switching is performed for each region. In the example illustrated in FIG. 23, a case is assumed where one frame is vertically divided into three and switching is performed for each region.

When the number of spots is increased and light intensity per spot is maintained, there is a possibility that power consumption increases to exceed safety standard for protecting eyes. In this respect, by switching the light emission in units of light emission regions, flexible adjustment can be performed. Switching of light emission may be performed for each frame, and may be performed for each block or the like in the frame. Furthermore, it is also possible to recognize a position of a target object to be subjected to the distance measurement and allow the region to emit light.

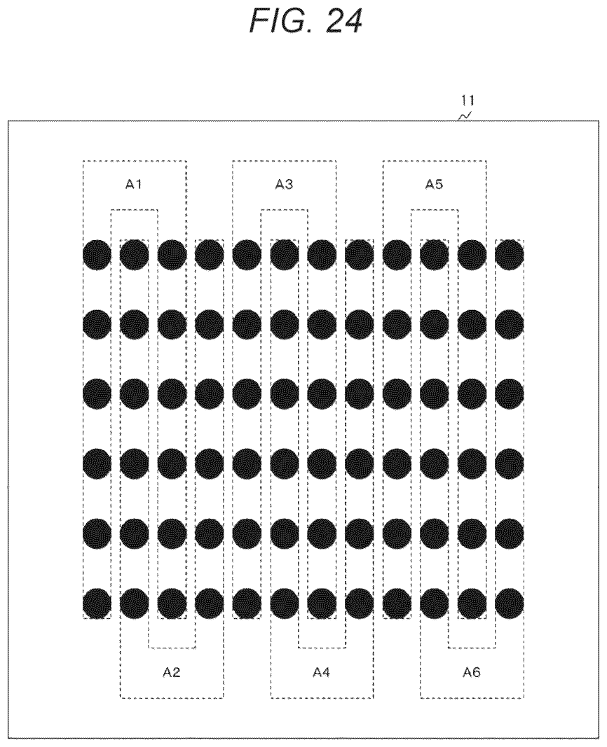

FIG. 24 is a diagram illustrating another example of grouping of the light emitting elements 11 according to a modification of the present technology. In this example, an example is illustrated in which grouping is performed for every two columns so that the light emitting elements 11 are differently combined for every columns. For example, first and third columns form a region A1, second and fourth columns form a region A2, fifth and seventh columns form a region A3, sixth and eighth columns form a region A4, ninth and 11th columns form a region A5, and 10th and 12th columns form a region A6. Therefore, switching of light emission may be controlled for every two columns. Therefore, it is possible to reduce power consumption caused by region switching and increase light output within the laser safety standard while taking multipath countermeasures.

### 3. Application Example

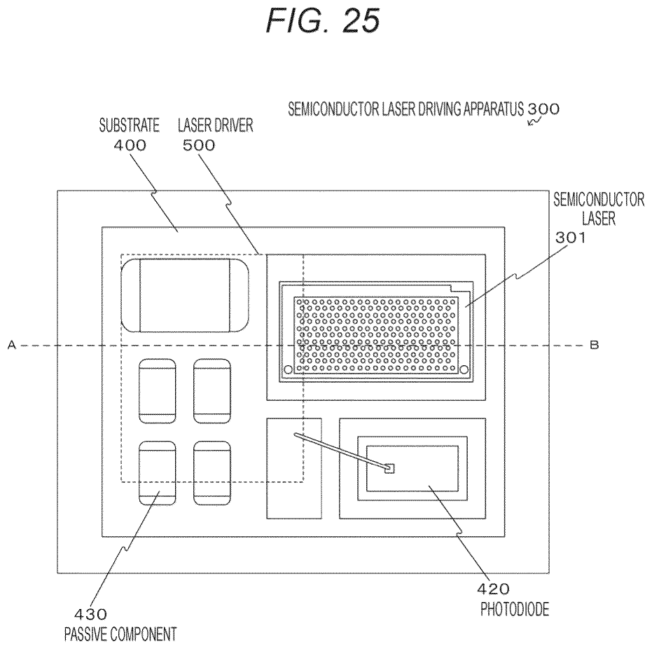

Next, an application example will be described. In the present application example, the present technology is configured as a semiconductor laser driving apparatus 300. FIG. 25 is a diagram illustrating an example of a top view of the semiconductor laser driving apparatus 300 in the application example. The semiconductor laser driving apparatus 300 is assumed to measure a distance by ToF. ToF has a feature of high depth accuracy, which is not as high as structured light, and of being able to operate without problems even in a dark environment. In addition, it is considered that there are many advantages in terms of simplicity of a device configuration, cost, and the like as compared with other methods such as a structured light and a stereo camera.

In the semiconductor laser driving apparatus 300, a semiconductor laser 301, a photodiode 420, and a passive component 430 are electrically connected and mounted by wire bonding on the surface of a substrate 400 incorporating a laser driver 500 (an example of a driving element). As the substrate 400, a printed wiring board is assumed. Here, the above-described illumination devices 1 and 1B can be applied to the semiconductor laser 301, and for example, the light receiving unit 210 in FIG. 1 can be applied as the photodiode.

The semiconductor laser 301 is a semiconductor device that emits a laser light by causing a current to flow through a PN junction of a compound semiconductor. Here, as the compound semiconductor to be used, for example, aluminum gallium arsenide (AlGaAs), indium gallium arsenide phosphorus (InGaAsP), aluminum gallium indium phosphorus (AlGaInP), gallium nitride (GaN), and the like are assumed.

The laser driver 500 is a driver integrated circuit (IC) for driving the semiconductor laser 301. The laser driver 500 is built in the substrate 400 in a face-up state. Since it is necessary to reduce the wiring inductance for electrical connection with the semiconductor laser 301, the wiring length is desirably as short as possible.

The photodiode 420 is a diode for detecting light. The photodiode 420 is used for automatic power control (APC) for monitoring the light intensity of the semiconductor laser 301 and maintaining the output of the semiconductor laser 301 constant.

The passive component 430 is a circuit component other than an active element such as a capacitor and a resistor. The passive component 430 includes a decoupling capacitor for driving the semiconductor laser 301.

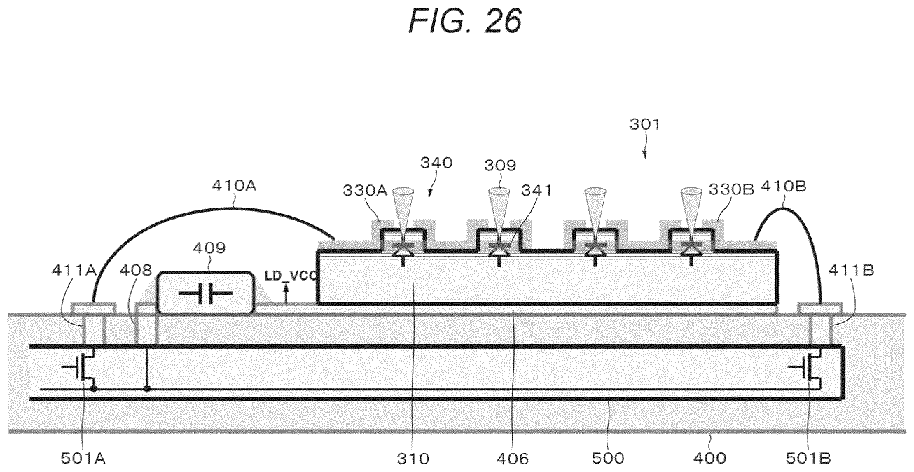

FIG. 26 is a diagram illustrating an example of a cross-sectional view of the semiconductor laser driving apparatus 300 in an application example of the present technology. As described above, the substrate 400 incorporates the laser driver 500, and the semiconductor laser 301 and the like are mounted on the surface thereof. Connection between the semiconductor laser 301 and the laser driver 500 in the substrate 400 is performed via a connection via 401. By using the connection via 401, the wiring length can be shortened.

The semiconductor laser 301 is assumed to be a vertical cavity surface emitting laser (VCSEL). The VCSEL has a substrate 310 as a substrate material, and a common anode is provided therebelow. The light emission points are formed as trapezoidal mesas each including a light emitting element 341.

The anode electrode of the light emitting element 341 is connected to a pattern 406 of signal lines on the substrate 400 via the connection layer. A cathode electrode of the light emitting element is connected to metal layers 330A and 330B, and one ends of driver elements 501A and 501B are connected to the metal layers 330A and 330B via wire bonding 410A and 410B. Here, the connection layer can be constituted by either silver paste or solder. The wire bonding 410A and 410B and the driver elements 510A and 510B are connected by connection vias 411A and 411B.

In addition, in the application example, since the light emission point of the semiconductor laser 301 is located immediately above the substrate 400, heat generated at the light emission point can be efficiently released to the component built-in substrate.

Further, the substrate 400 includes a thermal via for heat dissipation. Each component mounted on the substrate 400 is a heat source, and the heat generated in each component can be dissipated from the back surface of the substrate 400 by using the thermal vias.

As illustrated in FIG. 26, in the application example, a capacitance 409 is mounted as a decoupling capacitor on the substrate 400, and is connected between the pattern 406 and a ground (GND) 408. Since the capacitance 409 is provided as a decoupling capacitor, the charge stored in the capacitance 409 can be used as a drive current of the semiconductor laser 301. As described above, according to the application example, when the laser is modulated at high speed, the charge stored in the capacitance 409 mounted most recently of the semiconductor laser 301 becomes the drive current of the semiconductor laser 301, so that it is possible to realize higher speed modulation.

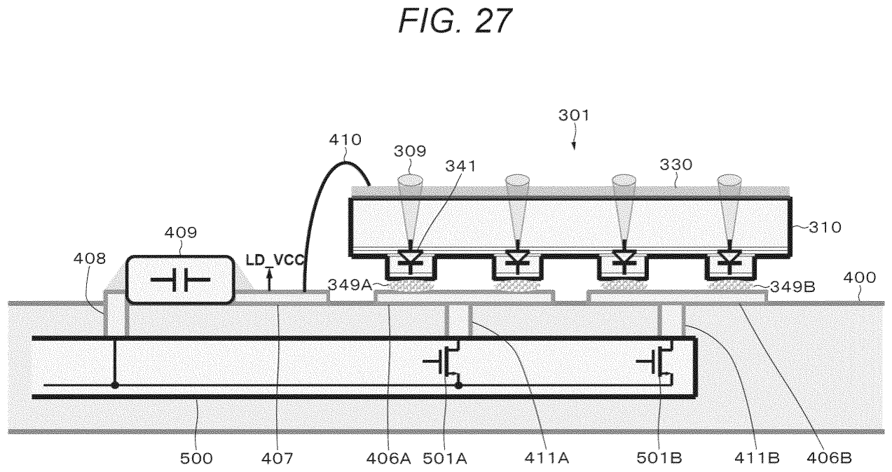

As illustrated in FIG. 27, the front and back surfaces of the light emitting element 341 may be disposed in opposite directions. In this case, emitted light 309 from the light emitting element 341 is emitted through the substrate 310. The cathode of the light emitting element 341 is connected to the pattern 406 of the signal line on the substrate 400 via bumps 349A and 349B, and is connected to one end of the driver elements 501A and 501B of the laser driver 500 built in the substrate 400 via the connection vias 411A and 411B. The other ends of the driver elements 501A and 501B are connected to the ground (GND) 408. A metal layer 330 is provided on the light emission point-side surface of the substrate 310, and is connected to a pattern 407 of the power supply of the substrate 400 via wire bonding 410. Here, the metal layer 330 may be a transparent electrode such as indium tin oxide (ITO). The side of the light emitting element 341 that is not the light emission point side is connected to the driver elements 501A and 501B via the bumps 349A and 349B, patterns 406A and 406B, and the connection vias 411A and 411B. Here, the bumps 349A and 349B can be constituted by any of gold (Au), copper (Cu), or solder.

Note that, the above embodiments illustrate examples for embodying the present technology, and matters in the embodiments and matters specifying the invention in claims have correspondence relationships. Similarly, the matters specifying the invention in the claims and matters having the same names in the embodiments of the present technology have correspondence relationships. However, the present technology is not limited to the embodiments and can be embodied by making various modifications to the embodiments without departing from the gist thereof.

Note that effects described in the present specification are merely examples and are not limited, and other effects may be provided.

Note that the present technology may also have a following configuration.

(1)

An illumination device including:
a light emitting element including a plurality of first light emission units and a plurality of second light emission units;
a first optical member that emits a plurality of first light emitted from the plurality of first light emission units and a plurality of second light emitted from the plurality of second light emission units in substantially parallel to each other;
a second optical member that shapes a beam shape of at least one of the plurality of first light or the plurality of second light, and emits the plurality of first light and the plurality of second light as light having different beam shapes; and
a third optical member,
in which the third optical member is disposed on optical paths of the plurality of first light and the plurality of second light, and an action on the plurality of first light by the third optical member is different from an action on the plurality of second light by the third optical member.
   (2)

The illumination device according to (1),
in which the third optical member does not act on the plurality of first light and refracts or diffracts the plurality of second light in a predetermined direction.
   (3)

The illumination device according to (1) or (2),
in which the plurality of first light emitted from the plurality of first light emission units is light emitted to an irradiation target object in a spot shape independent from each other, and
the plurality of second light emitted from the plurality of second light emission units is light with which the irradiation target object is irradiated in a substantially uniform manner in a predetermined range by a part of the second light being overlapped on the second light emitted from the second light emission units adjacent.
   (4)

The illumination device according to (3),
in which the third optical member is an optical member that increases an overlapping range in which the plurality of second light partially overlaps each other.
   (5)

The illumination device according to any one of (1) to (4),
in which the plurality of first light emitted from the plurality of first light emission units and the plurality of second light emitted from the plurality of second light emission units have different polarization characteristics.
   (6)

The illumination device according to any one of (1) to (5),
in which the third optical member is a polarization diffraction element.
   (7)

The illumination device according to any one of (1) to (6),
in which the third optical member is a liquid crystal element.
   (8)

The illumination device according to any one of (1) to (7),
in which the third optical member is metamaterial.
   (9)

A distance measuring device including:
an illumination device according to any one of (1) to (8);
a control unit that controls the illumination device;
a light receiving unit that receives reflected light reflected from an irradiation target object; and
a distance measuring unit that calculates a distance from image data obtained by the light receiving unit.

### REFERENCE SIGNS LIST

1 Illumination device
11 Light emitting element
12 Microlens array
13 Collimator lens
34 Diffraction element
35 ¼ wavelength plate
110, 120 Light emission unit
210 Light receiving unit
220 Control unit
230 Distance measuring unit
1000 Irradiation target object
L110, L120 Laser beam

1. An illumination device comprising:
a light emitting element including a plurality of first light emission units and a plurality of second light emission units;
a first optical member that emits a plurality of first light emitted from the plurality of first light emission units and a plurality of second light emitted from the plurality of second light emission units in substantially parallel to each other;
a second optical member that shapes a beam shape of at least one of the plurality of first light or the plurality of second light, and emits the plurality of first light and the plurality of second light as light having different beam shapes; and
a third optical member,
wherein the third optical member is disposed on optical paths of the plurality of first light and the plurality of second light, and an action on the plurality of first light by the third optical member is different from an action on the plurality of second light by the third optical member.

2. The illumination device according to claim 1,
wherein the third optical member does not act on the plurality of first light and refracts or diffracts the plurality of second light in a predetermined direction.

3. The illumination device according to claim 1,
wherein the plurality of first light emitted from the plurality of first light emission units is light emitted to an irradiation target object in a spot shape independent from each other, and
the plurality of second light emitted from the plurality of second light emission units is light with which the irradiation target object is irradiated in a substantially uniform manner in a predetermined range by a part of the second light being overlapped on the second light emitted from the second light emission units adjacent.

4. The illumination device according to claim 3,
wherein the third optical member is an optical member that increases an overlapping range in which the plurality of second light partially overlaps each other.

5. The illumination device according to claim 1,
wherein the plurality of first light emitted from the plurality of first light emission units and the plurality of second light emitted from the plurality of second light emission units have different polarization characteristics.

6. The illumination device according to claim 1,
wherein the third optical member is a polarization diffraction element.

7. The illumination device according to claim 1,
wherein the third optical member is a liquid crystal element.

8. The illumination device according to claim 1,
wherein the third optical member is metamaterial.

9. A distance measuring device comprising:
the illumination device according to claim 1;
a control unit that controls the illumination device;
a light receiving unit that receives reflected light reflected from an irradiation target object; and
a distance measuring unit that calculates a distance from image data obtained by the light receiving unit.
